(19) United States
(12) Patent Application Publication
(10) Pub. No.: US 2026/0068264 A1
(43) Pub. Date: Mar. 5, 2026

(54) SEMICONDUCTOR DEVICE

(71) Applicant: Mitsubishi Electric Corporation, Tokyo (JP)

(72) Inventors: Ryosuke KOBAYASHI, Tokyo (JP); Ichiro OMURA, Fukuoka (JP); Srikanth GOLLAPUDI, Fukuoka (JP)

(73) Assignee: Mitsubishi Electric Corporation, Tokyo (JP)

(21) Appl. No.: 19/261,753

(22) Filed: Jul. 7, 2025

(30) Foreign Application Priority Data
Aug. 30, 2024 (JP) 2024-148197

(51) Int. Cl. H10D 64/00; H10D 12/00; H10D 64/27

(52) U.S. Cl. CPC H10D 64/117; H10D 12/481; H10D 64/513; H10D 64/518

(57) ABSTRACT

A semiconductor device according to the present disclosure includes: a semiconductor substrate; a first trench provided in the semiconductor substrate to penetrate a fourth semiconductor layer, a third semiconductor layer, and a second semiconductor layer and reach a first semiconductor layer; an interlayer insulating film provided to cover the first trench; and a second trench provided in the semiconductor substrate to penetrate the third semiconductor layer and the second semiconductor layer and reach the first semiconductor layer, wherein the first trench has a lower electrode provided on the side of the second main surface and an upper electrode provided on the side of the first main surface with respect to the lower electrode, the second trench has a dummy electrode electrically connected to the first main electrode, and a maximum width of the dummy electrode is equal to or larger than a maximum width of the lower electrode.

### BACKGROUND OF THE INVENTION

### Field of the Invention

The present disclosure relates to a semiconductor device whose conduction is controlled by a gate signal.

### Description of the Background Art

Conventionally, there is disclosed a semiconductor device including a trench having an upper electrode and a lower electrode (see, for example, Japanese Patent Application Laid-Open No. 2014-60362, Japanese Patent Application Laid-Open No. 2019-12813, Japanese Patent Application Laid-Open No. 2017-147431, and Japanese Patent Application Laid-Open No. 2021-72418).

In the conventional semiconductor device, when high dI/dt (recovery current of antiparallel diodes) is applied to the semiconductor device in an OFF state, there is a possibility that a gate potential of the semiconductor device increases to cause erroneous turn-on.

Here, a mechanism in which the gate potential of the semiconductor device increases to cause the erroneous turn-on will be described by exemplifying a semiconductor device in which an upper electrode is connected to a gate potential and a lower electrode is connected to an emitter potential in a gate electrode division structure. When a voltage is applied between a collector and an emitter of the semiconductor device, holes accumulate around the lower electrode of a trench, and a displacement current flows from the collector to the lower electrode. Since the lower electrode has a small cross-sectional area and a high resistance value, the potential of the lower electrode increases. When the potential of the lower electrode is greater than the potential of the upper electrode, a displacement current flows from the lower electrode to the upper electrode. When the potential of the upper electrode exceeds a threshold voltage, the semiconductor device is erroneously turned on. When the semiconductor device constituting an inverter or the like is erroneously turned on, an arm short circuit occurs.

### SUMMARY

The present disclosure has been made to solve such a problem, and an object thereof is to provide a semiconductor device capable of suppressing the occurrence of erroneous turn-on.

A semiconductor device according to the present disclosure includes: a semiconductor substrate including a first semiconductor layer of a first conductivity type, a second semiconductor layer of the first conductivity type provided on the first semiconductor layer, a third semiconductor layer of a second conductivity type provided on the second semiconductor layer, and a fourth semiconductor layer of the first conductivity type selectively provided in an upper layer portion of the third semiconductor layer; a first main electrode provided on a side of a first main surface of the semiconductor substrate to be in contact with the fourth semiconductor layer; a second main electrode provided on a side of a second main surface facing the first main surface of the semiconductor substrate; a first trench provided in the semiconductor substrate to penetrate the fourth semiconductor layer, the third semiconductor layer, and the second semiconductor layer and reach the first semiconductor layer; an interlayer insulating film provided to cover the first trench; and a second trench provided in the semiconductor substrate to penetrate the third semiconductor layer and the second semiconductor layer and reach the first semiconductor layer, wherein the first trench has a lower electrode provided on the side of the second main surface and an upper electrode provided on the side of the first main surface with respect to the lower electrode, the second trench has a dummy electrode electrically connected to the first main electrode, and a maximum width of the dummy electrode is equal to or larger than a maximum width of the lower electrode.

According to the present disclosure, it is possible to suppress the occurrence of the erroneous turn-on.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device according to a first preferred embodiment;

FIG. 2 is a cross-sectional view of a semiconductor device according to a second modification of the first preferred embodiment;

FIG. 3 is a cross-sectional view of a semiconductor device according to a fourth modification of the first preferred embodiment;

FIG. 4 is a cross-sectional view of a semiconductor device according to a fifth modification of the first preferred embodiment;

FIG. 5 is a cross-sectional view of a semiconductor device according to a sixth modification of the first preferred embodiment;

FIG. 6 is a cross-sectional view of a semiconductor device according to a seventh modification of the first preferred embodiment;

FIG. 7 is a cross-sectional view of a semiconductor device according to a ninth modification of the first preferred embodiment;

FIG. 8 is a cross-sectional view of a semiconductor device according to an eleventh modification of the first preferred embodiment;

FIG. 9 is a cross-sectional view of a semiconductor device according to a twelfth modification of the first preferred embodiment; and

FIG. 10 is a plan view of a semiconductor device according to a thirteenth modification of the first preferred embodiment.

### DESCRIPTION OF THE PREFERRED EMBODIMENTS

### First Preferred Embodiment

Hereinafter, semiconductor devices according to preferred embodiments will be described with reference to the drawings. The semiconductor device is, for example, an insulated gate bipolar transistor (IGBT). Note that the same or corresponding components are denoted by the same reference signs, and repetition of the description may be omitted. In the following description, N and P represent conductivity types of a semiconductor. In the present disclosure, a first conductivity type is described as an N type, and a second conductivity type is described as a P type. These conductivity types may be reversed.

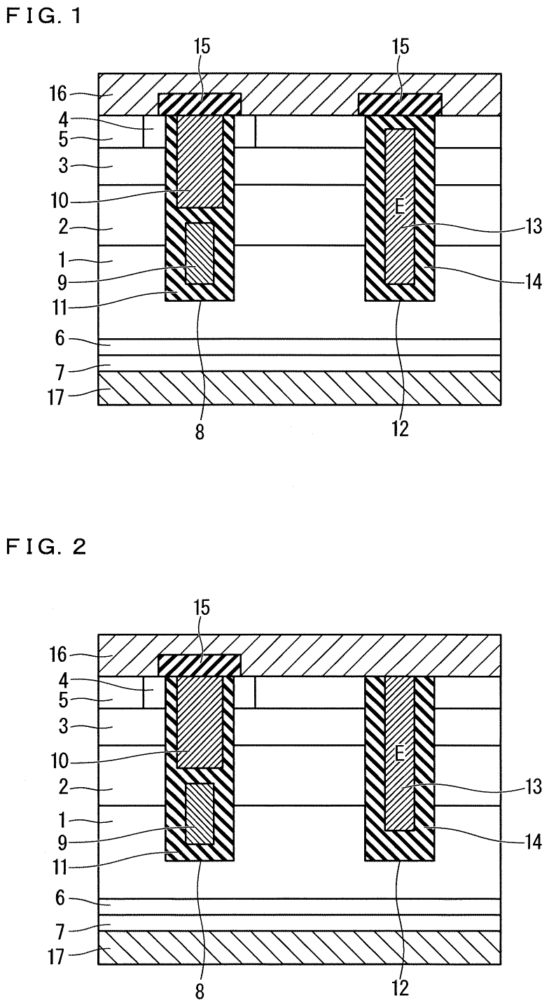

FIG. 1 is a cross-sectional view of a semiconductor device according to a first preferred embodiment. In FIG. 1, a semiconductor substrate ranges from an N+ emitter 4 and a P+ contact 5 to a P collector layer 7. In FIG. 1, upper ends of the N+ emitter 4 and the P+ contact 5 on the drawing are referred to as a first main surface of the semiconductor substrate, and a lower end of the P collector layer 7 on the drawing is referred to as a second main surface of the semiconductor substrate. The first main surface and the second main surface face each other.

As illustrated in FIG. 1, a carrier accumulation layer 2 of the N type is provided on the first main surface side of an N-drift layer 1 of the N type (on the N-drift layer 1). The N-drift layer 1 corresponds to a first semiconductor layer, and the carrier accumulation layer 2 corresponds to a second semiconductor layer.

A P base layer 3 of the P type is provided on the first main surface side of the carrier accumulation layer 2. The N+ emitter 4 of the N type and the P+ contact 5 of the P type are selectively provided in an upper layer portion (a surface layer portion on the first main surface side) of the P base layer 3. The P base layer 3 corresponds to a third semiconductor layer, and the N+ emitter 4 corresponds to a fourth semiconductor layer.

The semiconductor substrate is provided with a first trench 8 that penetrates the N+ emitter 4, the P base layer 3, and the carrier accumulation layer 2 and reaches the N-drift layer 1. The first trench 8 has a lower electrode 9 provided on the second main surface side and an upper electrode 10 provided on the first main surface side with respect to the lower electrode 9. In addition, the first trench 8 has an insulating film 11 provided on a side wall and a bottom of the first trench 8 so as to cover the lower electrode 9 and the upper electrode 10. In the insulating film 11, a portion provided on the side wall and the bottom of the first trench 8 so as to cover the lower electrode 9 is referred to as a lower insulating film, and a portion provided on the side wall of the first trench 8 so as to cover the upper electrode 10 is referred to as an upper insulating film. In addition, a portion sandwiched between the lower electrode 9 and the upper electrode 10 is referred to as a boundary insulating film. Note that the first trench 8 may have a tapered shape tapered from the first main surface toward the second main surface. In this case, the lower electrode 9 and the upper electrode 10 also have a tapered shape.

The semiconductor substrate is provided with a second trench 12 that penetrates the P+ contact 5, the P base layer 3, and the carrier accumulation layer 2 and reaches the N-drift layer 1. The second trench 12 has a dummy electrode 13 electrically connected to an emitter electrode 16. In addition, the second trench 12 has a dummy insulating film 14 provided on a side wall and a bottom of the second trench 12 so as to cover the dummy electrode 13. A thickness of the dummy insulating film 14 may be constant.

The dummy electrode 13 has a side face formed in a linear shape along the side wall of the second trench 12. Here, the linear shape refers to a continuous shape having no step. The second trench 12 may have a tapered shape tapered from the first main surface toward the second main surface. In this case, the dummy electrode 13 also has a tapered shape.

A maximum width of the dummy electrode 13 is equal to or larger than a maximum width of the lower electrode 9. For example, the maximum width of the dummy electrode 13 is 1.1 times or more the maximum width of the lower electrode 9. Here, the width of the dummy electrode 13 refers to a length of the dummy electrode 13 in a direction perpendicular to a direction connecting the first main surface and the second main surface. The same applies to the width of the lower electrode 9.

On the first main surface of the semiconductor substrate, an interlayer insulating film 15 is provided so as to cover each of the first trench 8 and the second trench 12. The emitter electrode 16 is provided so as to cover the first main surface (the N+ emitter 4 and the P+ contact 5) of the semiconductor substrate and the interlayer insulating film 15. The emitter electrode 16 corresponds to a first main electrode.

An N buffer 6 of the N type is provided on the second main surface side of the N-drift layer 1. The P collector layer 7 is provided on the second main surface side of the N buffer 6. A collector electrode 17 is provided so as to cover the second main surface (P collector layer 7) of the semiconductor substrate. The collector electrode 17 corresponds to a second main electrode.

In the first preferred embodiment, the second trench 12 is provided adjacent to the first trench 8 with a space therebetween, and the dummy electrode 13 of the second trench 12 has a large cross-sectional area, and thus has low resistance. Therefore, when high dI/dt (recovery current of antiparallel diodes) is applied to the semiconductor device in an OFF state, holes are likely to flow to the dummy electrode 13 of the second trench 12. As a result, a potential of the lower electrode 9 is less likely to increase, and erroneous turn-on of the semiconductor device can be suppressed.

### First Modification

In a semiconductor device according to a first modification, a thickness of a lower insulating film provided at the bottom of the first trench 8 and a thickness of a dummy insulating film provided at the bottom of the second trench 12 are thinner than a thickness of a dummy insulating film provided on the side wall of the second trench 12. Here, the thickness of the lower insulating film provided at the bottom of the first trench 8 refers to a length of the lower insulating film in the direction connecting the first main surface and the second main surface.

An insulating film has low resistance at a site where a thickness of the insulating film is thin. Therefore, holes are likely to pass particularly from the bottom of the second trench 12, which can contribute to the suppression of the erroneous turn-on of the semiconductor device.

### Second Modification

FIG. 2 is a cross-sectional view of a semiconductor device according to a second modification. As illustrated in FIG. 2, the dummy electrode 13 is covered with the emitter electrode 16. Specifically, the interlayer insulating film 15 is not provided on the second trench 12, and the dummy electrode 13 is in contact with the emitter electrode 16.

Since the interlayer insulating film 15 is not provided on the second trench 12, wiring resistance from the dummy electrode 13 to the emitter electrode 16 is extremely low, and holes directly flow to the emitter electrode 16 through the dummy electrode 13. Therefore, it is possible to contribute to the suppression of the erroneous turn-on of the semiconductor device.

### Third Modification

In a semiconductor device according to a third modification, the thickness of the dummy insulating film 14 is thinner than the thickness of the lower insulating film provided on the side wall and the bottom of the first trench 8 so as to cover the lower electrode 9.

Since the cross-sectional area of the dummy electrode 13 is increased by decreasing the thickness of the dummy insulating film 14, the wiring resistance from the dummy electrode 13 to the emitter electrode 16 can be reduced. In addition, since parasitic capacitance between the emitter and the collector formed by the dummy insulating film 14 is increased by decreasing the thickness of the dummy insulating film 14, impedance of the parasitic capacitance between the emitter and the collector can be reduced, and holes are likely to flow to the dummy electrode 13 of the second trench 12.

### Fourth Modification

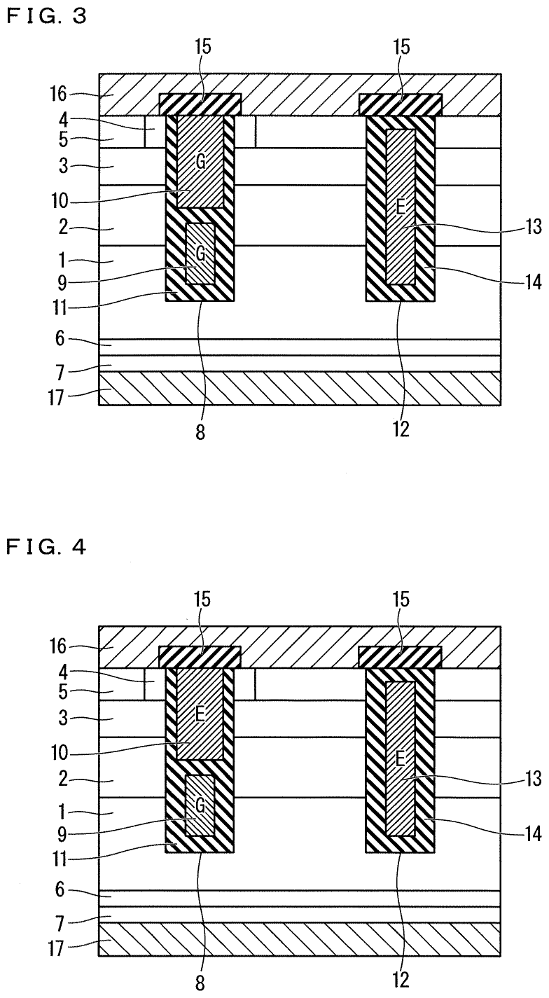

FIG. 3 is a cross-sectional view of a semiconductor device according to a fourth modification. As illustrated in FIG. 3, the lower electrode 9 and the upper electrode 10 are connected to a gate potential (gate electrode which is not illustrated).

A total cross-sectional area of the two electrodes of the lower electrode 9 and the upper electrode 10 can be made smaller than a cross-sectional area in a case where the lower electrode 9 and the upper electrode 10 are connected to form one electrode. When the cross-sectional area is reduced in this manner, wiring resistance from each of the lower electrode 9 and the upper electrode 10 to the gate electrode increases. Therefore, holes are likely to flow toward the second trench 12.

### Fifth Modification

FIG. 4 is a cross-sectional view of a semiconductor device according to a fifth modification. As illustrated in FIG. 4, the lower electrode 9 is connected to the gate potential, and the upper electrode 10 is connected to the emitter electrode 16.

Since only the lower electrode 9 is connected to the gate potential, a cross-sectional area of the electrode connected to the gate potential decreases and the wiring resistance to the gate electrode increases as compared with the semiconductor device according to the fourth modification. Therefore, holes are likely to flow to the second trench 12 as compared with the semiconductor device according to the fourth modification.

Note that a conventional structure and structures described in the first preferred embodiment and the first to fifth modifications may be combined in a single element, or a plurality of structures among the structures described in the first preferred embodiment and the first to fifth modifications may be combined in a single element. This can further suppress the occurrence of the erroneous turn-on.

### Sixth Modification

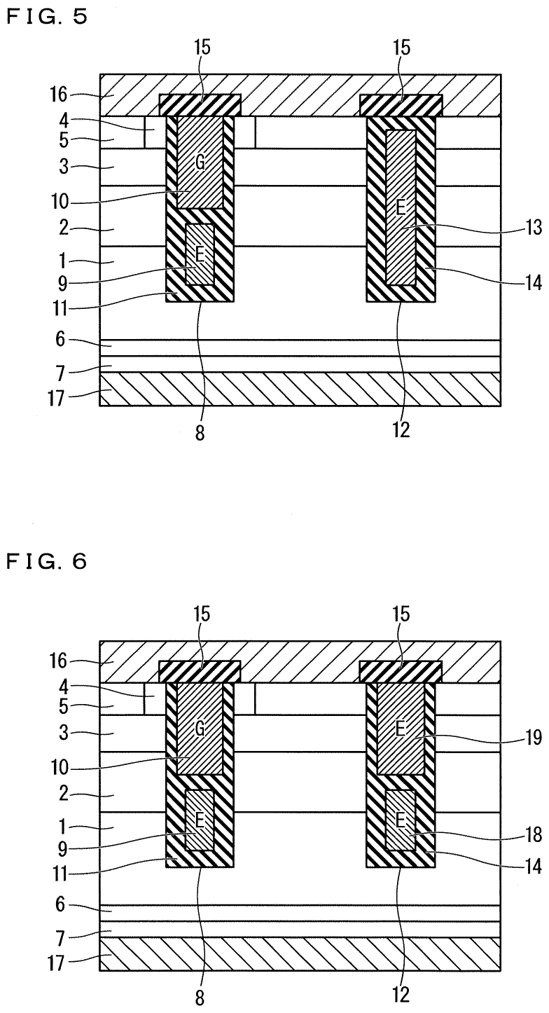

FIG. 5 is a cross-sectional view of a semiconductor device according to a sixth modification. As illustrated in FIG. 5, the lower electrode 9 is connected to the emitter electrode 16, and the upper electrode 10 is connected to the gate potential.

Since the lower electrode 9 is not connected to the gate potential, an increase in the potential of the upper electrode 10 can be suppressed even if holes are accumulated in the lower electrode 9. Therefore, it is possible to contribute to the suppression of the erroneous turn-on of the semiconductor device.

### Seventh Modification

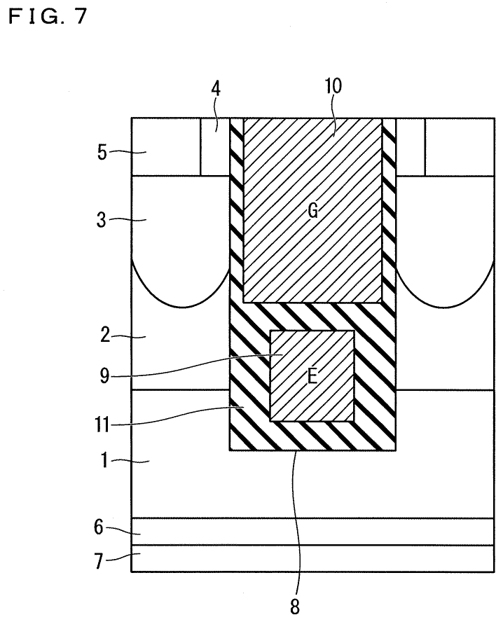

FIG. 6 is a cross-sectional view of a semiconductor device according to a seventh modification. As illustrated in FIG. 6, the second trench 12 has a lower dummy electrode 18 provided on the second main surface side and an upper dummy electrode 19 provided on the first main surface side with respect to the lower dummy electrode 18. The lower dummy electrode 18 and the upper dummy electrode 19 are electrically connected to the emitter electrode 16. A width of the upper dummy electrode 19 is larger than a width of the lower dummy electrode 18.

Although a case where a configuration of the first trench 8 is the same as that in FIG. 5 is illustrated as an example in FIG. 6, the configuration of the first trench 8 may be the same as that in FIG. 3 or 4.

Since the width of the upper dummy electrode 19 is made larger than the width of the lower dummy electrode 18, a total cross-sectional area of the lower dummy electrode 18 and the upper dummy electrode 19 can be increased, so that holes are likely to flow toward the second trench 12. In addition, since a film thickness of a portion of the dummy insulating film 14 provided on the side wall of the second trench 12 so as to cover the upper dummy electrode 19 is thin, the parasitic capacitance between the emitter and the collector increases, and the impedance of the parasitic capacitance between the emitter and the collector can be reduced. As a result, the holes are likely to flow to the second trench 12 side, and the increase in the potential of the upper electrode 10 can be suppressed.

### Eighth Modification

In a semiconductor device according to an eighth modification, the second trench 12 is arranged on at least one of left and right sides of the first trench 8 with a space therebetween.

Although the second trench 12 is arranged on the right side of the first trench 8 in the example of FIG. 1, the present disclosure is not limited thereto. The second trench 12 may be arranged on the left side of the first trench 8, or may be arranged on each of the right and left sides of the first trench 8. In addition, the first trench 8 and the second trench 12 may be alternately arranged, the first trench 8, the first trench 8, and the second trench 12 may be arranged in this order from left, or the second trench 12, the first trench 8, the first trench 8, and the second trench 12 may be arranged in this order from left. In this manner, the first trench 8 and the second trench 12 may be arranged in any manner as necessary.

Since the second trench 12 is arranged on at least one of the left and right sides of the first trench 8 with a space therebetween, holes are likely to flow toward the second trench 12.

### Ninth Modification

FIG. 7 is a cross-sectional view of a semiconductor device according to a ninth modification. In FIG. 7, the first trench 8 is mainly focused, and the second trench 12, the interlayer insulating film 15, the emitter electrode 16, and the collector electrode 17 are not illustrated. As illustrated in FIG. 7, an interface between the carrier accumulation layer 2 and the P base layer 3 is curved toward the second main surface.

Although a case where a configuration of the first trench 8 is the same as that in FIG. 5 is illustrated as an example in FIG. 7, the configuration of the first trench 8 may be the same as that in FIG. 3 or 4. In addition, the second trench 12 may have the dummy electrode 13 as illustrated in FIG. 1, and may have the lower dummy electrode 18 and the upper dummy electrode 19 as illustrated in FIG. 6.

Since the interface between the carrier accumulation layer 2 and the P base layer 3 is curved toward the second main surface, holes can be suppressed from flowing into the upper electrode 10.

### Tenth Modification

In a semiconductor device according to a tenth modification, materials of the lower electrode 9, the upper electrode 10, and the dummy electrode 13 are metal. The metal is, for example, aluminum, tungsten, or the like.

Since the materials of the lower electrode 9, the upper electrode 10, and the dummy electrode 13 are metal, the resistance of each electrode can be reduced.

When the second trench 12 includes the lower dummy electrode 18 and the upper dummy electrode 19 as illustrated in FIG. 6, materials of the lower dummy electrode 18 and the upper dummy electrode 19 may be metal.

### Eleventh Modification

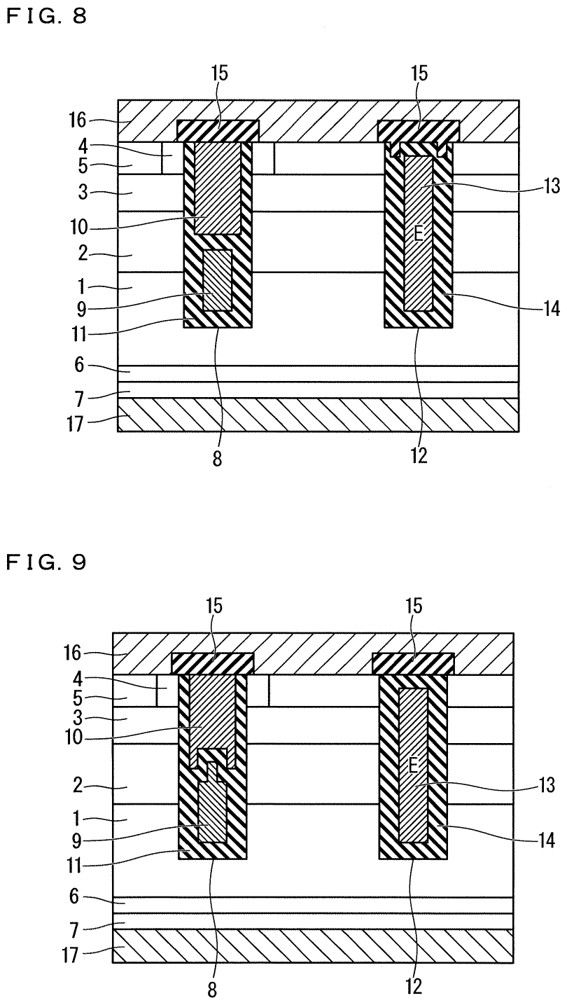

FIG. 8 is a cross-sectional view of a semiconductor device according to an eleventh modification. As illustrated in FIG. 8, a face of the dummy insulating film 14 on the first main surface side has a recessed shape. Specifically, a face of the dummy insulating film 14 in contact with the interlayer insulating film 15 has a recessed shape.

Since the face of the dummy insulating film 14 on the first main surface side is formed in the recessed shape, the area of the dummy electrode 13 in contact with the emitter electrode 16 increases, and the resistance of the dummy electrode 13 can be reduced.

Note that a configuration of the first trench 8 may be the same as that in any one of FIGS. 3, 4, and 5. The second trench 12 may have the dummy electrode 13 as illustrated in FIG. 1, and may have the lower dummy electrode 18 and the upper dummy electrode 19 as illustrated in FIG. 6.

### Twelfth Modification

FIG. 9 is a cross-sectional view of a semiconductor device according to a twelfth modification. As illustrated in FIG. 9, a face of the lower electrode 9 facing the upper electrode 10 (the face on the first main surface side) has a projecting shape. A face of the upper electrode 10 facing the lower electrode 9 (the face on the second main surface side) has a recessed shape. That is, the projecting shape of the lower electrode 9 and the recessed shape of the upper electrode 10 face each other.

Since the face of the lower electrode 9 facing the upper electrode 10 (the face on the first main surface side) is formed in the projecting shape and the face of the upper electrode 10 facing the lower electrode 9 (the face on the second main surface side) is formed in the recessed shape, resistance of an entrance of holes into the upper electrode 10 increases, and the increase in the potential of the upper electrode 10 can be suppressed.

Note that a configuration of the first trench 8 may be the same as that in any one of FIGS. 3, 4, and 5 as long as shapes of the lower electrode 9 and the upper electrode 10 are the shapes illustrated in FIG. 9. The second trench 12 may have the dummy electrode 13 as illustrated in FIG. 1, and may have the lower dummy electrode 18 and the upper dummy electrode 19 as illustrated in FIG. 6.

### Thirteenth Modification

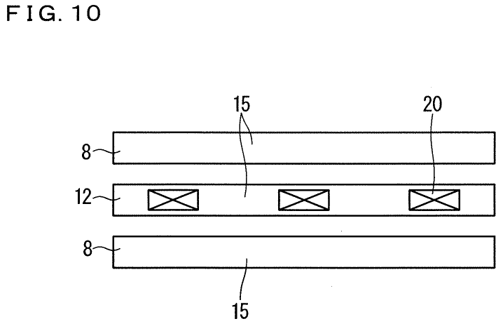

FIG. 10 is a plan view of a semiconductor device according to a thirteenth modification. FIG. 10 does not illustrate the N+ emitter 4, the P+ contact 5, and the emitter electrode 16.

As illustrated in FIG. 10, in the semiconductor device according to the thirteenth modification, contact holes 20, which are openings of the interlayer insulating film 15, are provided at equal intervals along an extending direction of the second trench 12 in plan view. The dummy electrode 13 is connected to the emitter electrode 16 through the contact holes 20.

In a case where the interlayer insulating film 15 is not provided on the second trench 12 (see, for example, FIG. 2), a hole discharge effect is high, a conductivity modulation effect in the semiconductor device at the time of conduction is lowered, and an on-voltage (Vce(sat)) increases. As in the semiconductor device according to the thirteenth modification, when the contact holes 20 are provided at equal intervals (that is, the interlayer insulating film 15 is provided on a part of the second trench 12) along the extending direction of the second trench 12 in plan view, the increase in the on-voltage can be suppressed.

### Fourteenth Modification

In a semiconductor device according to a fourteenth modification, contact holes, which are openings of the interlayer insulating film 15, are respectively provided at both ends of the second trench 12 along the extending direction of the second trench 12 in plan view. The dummy electrode 13 is connected to the emitter electrode 16 through the contact holes.

Also in the configuration of the semiconductor device according to the fourteenth modification, the same effects as those of the thirteenth modification can be obtained.

Note that the preferred embodiment can be appropriately modified or omitted within the scope of the present disclosure.

### Appendixes

Hereinafter, various aspects of the present disclosure will be collectively described as appendixes.

### (Appendix 1)

A semiconductor device comprising:
a semiconductor substrate including a first semiconductor layer of a first conductivity type, a second semiconductor layer of the first conductivity type provided on the first semiconductor layer, a third semiconductor layer of a second conductivity type provided on the second semiconductor layer, and a fourth semiconductor layer of the first conductivity type selectively provided in an upper layer portion of the third semiconductor layer;
a first main electrode provided on a side of a first main surface of the semiconductor substrate to be in contact with the fourth semiconductor layer;
a second main electrode provided on a side of a second main surface facing the first main surface of the semiconductor substrate;
a first trench provided in the semiconductor substrate to penetrate the fourth semiconductor layer, the third semiconductor layer, and the second semiconductor layer and reach the first semiconductor layer;
an interlayer insulating film provided to cover the first trench; and
a second trench provided in the semiconductor substrate to penetrate the third semiconductor layer and the second semiconductor layer and reach the first semiconductor layer, wherein
the first trench has a lower electrode provided on the side of the second main surface and an upper electrode provided on the side of the first main surface with respect to the lower electrode,
the second trench has a dummy electrode electrically connected to the first main electrode, and
a maximum width of the dummy electrode is equal to or larger than a maximum width of the lower electrode.

### (Appendix 2)

The semiconductor device according to Appendix 1, wherein the dummy electrode has a side face formed in a linear shape along a side wall of the second trench.

### (Appendix 3)

The semiconductor device according to Appendix 1 or 2, wherein the maximum width of the dummy electrode is 1.1 times or more the maximum width of the lower electrode.

### (Appendix 4)

The semiconductor device according to any one of Appendixes 1 to 3, wherein each of the first trench and the second trench has a tapered shape tapered from the first main surface toward the second main surface.

### (Appendix 5)

The semiconductor device according to any one of Appendixes 1 to 4, wherein
the first trench has a lower insulating film provided on a side wall and a bottom of the first trench to cover the lower electrode,
the second trench has a dummy insulating film provided on a side wall and a bottom of the second trench to cover the dummy electrode, and
a thickness of the lower insulating film provided at the bottom of the first trench and a thickness of the dummy insulating film provided at the bottom of the second trench are thinner than a thickness of the dummy insulating film provided on the side wall of the second trench.

### (Appendix 6)

The semiconductor device according to any one of Appendixes 1 to 5, wherein the dummy electrode is covered with the first main electrode.

(Appendix 7)

The semiconductor device according to any one of Appendixes 1 to 4 and 6, wherein
the first trench has a lower insulating film provided on a side wall and a bottom of the first trench to cover the lower electrode,
the second trench has a dummy insulating film provided on a side wall and a bottom of the second trench to cover the dummy electrode, and
a thickness of the dummy insulating film is thinner than a thickness of the lower insulating film.

### (Appendix 8)

The semiconductor device according to any one of Appendixes 1 to 7, wherein the lower electrode and the upper electrode are connected to a gate potential.

### (Appendix 9)

The semiconductor device according to any one of Appendixes 1 to 7, wherein the upper electrode is electrically connected to the first main electrode.

### (Appendix 10)

The semiconductor device according to any one of Appendixes 1 to 7, wherein the lower electrode is electrically connected to the first main electrode.

### (Appendix 11)

The semiconductor device according to any one of Appendixes 1 to 10, wherein
the dummy electrode has a lower dummy electrode provided on the side of the second main surface and an upper dummy electrode provided on the side of the first main surface with respect to the lower dummy electrode,
the lower dummy electrode and the upper dummy electrode are electrically connected to the first main electrode, and
a width of the upper dummy electrode is larger than a width of the lower dummy electrode.

### (Appendix 12)

The semiconductor device according to any one of Appendixes 1 to 11, wherein the second trench is arranged on at least one of left and right sides of the first trench with a space between the first trench and the second trench.

### (Appendix 13)

The semiconductor device according to any one of Appendixes 1 to 12, wherein an interface between the second semiconductor layer and the third semiconductor layer is curved toward the second main surface.

### (Appendix 14)

The semiconductor device according to any one of Appendixes 1 to 13, wherein materials of the lower electrode, the upper electrode, and the dummy electrode are metal.

### (Appendix 15)

The semiconductor device according to any one of Appendixes 1 to 14, wherein
the second trench has a dummy insulating film provided on a side wall and a bottom of the second trench to cover the dummy electrode, and
a face of the dummy insulating film on the side of the first main surface has a recessed shape.

### (Appendix 16)

The semiconductor device according to any one of Appendixes 1 to 15, wherein
a face of the lower electrode facing the upper electrode has a projecting shape, and
a face of the upper electrode facing the lower electrode has a recessed shape.
   (Appendix 17) The semiconductor device according to any one of Appendixes 1 to 16, wherein
the interlayer insulating film is provided to cover the second trench,
contact holes, which are openings of the interlayer insulating film, are provided at equal intervals along an extending direction of the second trench in plan view, and
the dummy electrode is connected to the first main electrode through the contact holes.

### (Appendix 18)

The semiconductor device according to any one of Appendixes 1 to 16, wherein
the interlayer insulating film is provided to cover the second trench,
contact holes, which are openings of the interlayer insulating film, are respectively provided at both ends of the second trench along an extending direction of the second trench in plan view, and
the dummy electrode is connected to the first main electrode through the contact holes.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate including a first semiconductor layer of a first conductivity type, a second semiconductor layer of the first conductivity type provided on the first semiconductor layer, a third semiconductor layer of a second conductivity type provided on the second semiconductor layer, and a fourth semiconductor layer of the first conductivity type selectively provided in an upper layer portion of the third semiconductor layer;
a first main electrode provided on a side of a first main surface of the semiconductor substrate to be in contact with the fourth semiconductor layer;
a second main electrode provided on a side of a second main surface facing the first main surface of the semiconductor substrate;
a first trench provided in the semiconductor substrate to penetrate the fourth semiconductor layer, the third semiconductor layer, and the second semiconductor layer and reach the first semiconductor layer;
an interlayer insulating film provided to cover the first trench; and
a second trench provided in the semiconductor substrate to penetrate the third semiconductor layer and the second semiconductor layer and reach the first semiconductor layer, wherein
the first trench has a lower electrode provided on the side of the second main surface and an upper electrode provided on the side of the first main surface with respect to the lower electrode,
the second trench has a dummy electrode electrically connected to the first main electrode, and
a maximum width of the dummy electrode is equal to or larger than a maximum width of the lower electrode.

2. The semiconductor device according to claim 1, wherein the dummy electrode has a side face formed in a linear shape along a side wall of the second trench.

3. The semiconductor device according to claim 1, wherein the maximum width of the dummy electrode is 1.1 times or more the maximum width of the lower electrode.

4. The semiconductor device according to claim 1, wherein each of the first trench and the second trench has a tapered shape tapered from the first main surface toward the second main surface.

5. The semiconductor device according to claim 1, wherein
the first trench has a lower insulating film provided on a side wall and a bottom of the first trench to cover the lower electrode,
the second trench has a dummy insulating film provided on a side wall and a bottom of the second trench to cover the dummy electrode, and
a thickness of the lower insulating film provided at the bottom of the first trench and a thickness of the dummy insulating film provided at the bottom of the second trench are thinner than a thickness of the dummy insulating film provided on the side wall of the second trench.

6. The semiconductor device according to claim 1, wherein the dummy electrode is covered with the first main electrode.

7. The semiconductor device according to claim 1, wherein
the first trench has a lower insulating film provided on a side wall and a bottom of the first trench to cover the lower electrode,
the second trench has a dummy insulating film provided on a side wall and a bottom of the second trench to cover the dummy electrode, and
a thickness of the dummy insulating film is thinner than a thickness of the lower insulating film.

8. The semiconductor device according to claim 1, wherein the lower electrode and the upper electrode are connected to a gate potential.

9. The semiconductor device according to claim 1, wherein the upper electrode is electrically connected to the first main electrode.

10. The semiconductor device according to claim 1, wherein the lower electrode is electrically connected to the first main electrode.

11. The semiconductor device according to claim 1, wherein
the dummy electrode has a lower dummy electrode provided on the side of the second main surface and an upper dummy electrode provided on the side of the first main surface with respect to the lower dummy electrode,
the lower dummy electrode and the upper dummy electrode are electrically connected to the first main electrode, and
a width of the upper dummy electrode is larger than a width of the lower dummy electrode.

12. The semiconductor device according to claim 1, wherein the second trench is arranged on at least one of left and right sides of the first trench with a space between the first trench and the second trench.

13. The semiconductor device according to claim 1, wherein an interface between the second semiconductor layer and the third semiconductor layer is curved toward the second main surface.

14. The semiconductor device according to claim 1, wherein materials of the lower electrode, the upper electrode, and the dummy electrode are metal.

15. The semiconductor device according to claim 1, wherein
the second trench has a dummy insulating film provided on a side wall and a bottom of the second trench to cover the dummy electrode, and
a face of the dummy insulating film on the side of the first main surface has a recessed shape.

16. The semiconductor device according to claim 1, wherein
a face of the lower electrode facing the upper electrode has a projecting shape, and
a face of the upper electrode facing the lower electrode has a recessed shape.

17. The semiconductor device according to claim 1, wherein
the interlayer insulating film is provided to cover the second trench,
contact holes, which are openings of the interlayer insulating film, are provided at equal intervals along an extending direction of the second trench in plan view, and
the dummy electrode is connected to the first main electrode through the contact holes.

18. The semiconductor device according to claim 1, wherein
the interlayer insulating film is provided to cover the second trench,
contact holes, which are openings of the interlayer insulating film, are respectively provided at both ends of the second trench along an extending direction of the second trench in plan view, and
the dummy electrode is connected to the first main electrode through the contact holes.
